(19) United States
(12) Patent Application Publication
(10) Pub. No.: US 2014/0196749 A1
(43) Pub. Date: Jul. 17, 2014

(54) CRYOGENIC LIQUID CLEANING APPARATUS AND METHODS

(71) Applicant: Applied Materials, Inc., Santa Clara, CA (US)

(72) Inventors: Jianshe Tang, San Jose, CA (US); Sidney P. Huey, Fremont, CA (US); Lakshmanan Karuppiah, San Jose, CA (US)

(21) Appl. No.: 14/146,382

(22) Filed: Jan. 2, 2014

Related U.S. Application Data
(60) Provisional application No. 61/752,732, filed on Jan. 15, 2013.

(51) Int. Cl. H01L 21/67; H01L 21/02

(52) U.S. Cl. CPC H01L 21/67051; H01L 21/02101
USPC 134/7; 134/102.1; 134/19

(57) ABSTRACT

A cryogenic cleaning apparatus is disclosed. The cryogenic cleaning apparatus has a source of cryogen, a nozzle coupled to the source of cryogen, the nozzle including a main passage adapted to receive the cryogen, one or more auxiliary gas inlets adapted to supply an auxiliary gas to mix with the cryogen either within the nozzle or at a nozzle exit of the nozzle to produce cryogen droplets, and a heated holder adapted to receive a substrate to be cleaned. Cryogenic cleaning methods adapted to clean substrates are provided, as are numerous other aspects.

### RELATED APPLICATIONS

The present application claims priority to U.S. Provisional Application 61/752,732 filed Jan. 15, 2013, and entitled “CRYOGENIC LIQUID CLEANING APPARATUS AND METHODS” which is hereby incorporated herein for all purposes.

### FIELD

The invention relates generally to semiconductor device manufacturing, and more particularly to a methods and apparatus adapted to clean a substrate surface using a cryogenic liquid.

### BACKGROUND

Within semiconductor substrate manufacturing, a planarization process may be used to remove various layers, such as oxides, copper, or the like. Planarization may be accomplished by pressing an abrasive disc-brush polishing pad containing a polishing slurry against the substrate. Following this planarization process, a cleaning process may be utilized to remove remaining polishing slurry and/or particles from the substrate.

In some instances, certain particles are very difficult to remove from the substrate's surface. Accordingly, improved cleaning apparatus and methods are sought.

### SUMMARY

In a first aspect, a cryogenic cleaning apparatus is provided. The cryogenic cleaning apparatus includes a source of cryogen adapted to deliver a cryogen, a nozzle coupled to the source of cryogen, the nozzle including a main passage adapted to receive the cryogen and one or more auxiliary gas inlets adapted to supply an auxiliary gas from an auxiliary gas source and to mix with the cryogen either within the nozzle or at a nozzle exit of the nozzle, and a heated holder adapted to receive a substrate to be cleaned.

In another aspect, a method of cleaning a substrate is provided. The method includes providing a substrate in a heated holder, heating the substrate to an operational temperature above room temperature, and spraying a cryogen onto a surface of the substrate from a nozzle wherein particles are dislodged from the surface using a combination of momentum transfer and a thermophoretic force.

Other features and aspects of the invention will become more fully apparent from the following detailed description of example embodiments, the appended claims, and the accompanying drawings.

### BRIEF DESCRIPTION OF THE DRAWINGS

FIG. 1 illustrates a schematic cross-sectioned side view of a cryogenic cleaning apparatus according to embodiments.

FIG. 2 illustrates a partially cross-sectioned side view of another cryogenic cleaning apparatus according to embodiments.

FIGS. 3A and 3B illustrate a cross-sectioned side view and a top plan view, respectively, of a heated substrate holder that may be used in cryogenic cleaning apparatus according to embodiments.

FIGS. 4A and 4B illustrate a cross-sectioned side view and a top plan view, respectively, of another heated substrate holder that may be used in cryogenic cleaning apparatus according to embodiments.

FIG. 5 illustrates a flowchart of a method of cleaning a substrate according to embodiments.

### DETAILED DESCRIPTION

Embodiments described herein relate to methods and apparatus adapted to clean a surface of a substrate using a cryogen. The cleaning methods and apparatus may be useful for cleaning a surface of a substrate (e.g., a semiconductor wafer) after a polishing process in semiconductor device manufacturing. In particular, the cleaning methods and apparatus may be useful for removing small particles (e.g., nm or smaller) from a surface of a substrate. Small particles may be difficult to remove because of Van der Waal attraction forces.

In one or more embodiments, auxiliary gas-assisted cryogenic liquid atomization may be used to generate liquid droplets (e.g., frozen cryogen droplets) that may be sprayed onto a surface of a substrate. In some embodiments, the cryogenic liquid may be argon (Ar) and the auxiliary gas may be nitrogen (N2). Alternatively, the cryogenic liquid may instead be N2 or CO₂, and the auxiliary gas may instead be He or Ar. The sprayed on droplets may detach and/or move small particles from the substrate surface by at least momentum transfer, which may be sufficient to overcome any Van der Waal attraction forces that may exist on the substrate surface. Momentum transfer involves a transfer of an amount of momentum from a moving particle to another particle with which the moving particle collides.

Small particles on the substrate surface may also be detached and/or moved off the substrate surface by a thermophoretic force, which may also be sufficient to overcome any Van der Waal attraction forces that may exist on the substrate surface. A thermophoretic force may be created by a temperature gradient wherein heated particles colliding with cooler particles may push the cooler particles away from a higher temperature region to a lower temperature region. The cleaning methods and apparatus may include a heated holder upon which a substrate is received. The heated holder may heat the substrate, which in turn may increase the temperature gradient between the substrate and the sprayed on cryogenic liquid droplets beyond that which may already exist between a room-temperature substrate and the sprayed on cryogenic liquid droplets. This may therefore increase the strength of the thermophoretic force and may, thus, improve the effectiveness of the cleaning process.

The cleaning methods and apparatus do not utilize a vacuum chamber, and may be integrated with a wet process chamber or a dry chamber after wafer drying. In addition to post CMP (chemical-mechanical planarization) cleaning, the cleaning methods and apparatus may also be used for FEOL (front-end-of-the-line) damage-free cleaning, such as, e.g., post-etch cleaning.

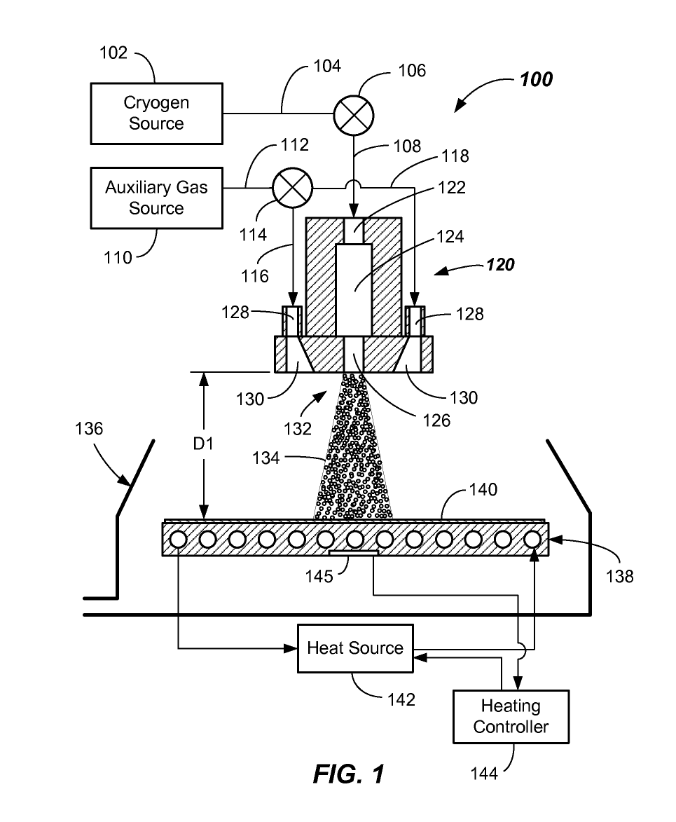

These and other aspects of embodiments of the invention are described below with reference to FIGS. 1-5 herein.

FIG. 1 illustrates a cross-sectioned side view of a cryogenic cleaning apparatus 100 and components thereof in accordance with one or more embodiments. Cryogenic cleaning apparatus 100 may include a cryogen source 102 configured to deliver a cryogen via a conduit 104, a flow control device 106, and a conduit 108 (which is represented by an arrow in FIG. 1 to illustrate direction of flow). Cryogen source 102 may include, e.g., N2, Ar, or CO₂. In other embodiments, other suitable gases may be used. Conduits 104 and 108 may be made of any material suitable for carrying a cryogen. Flow control device 106, which may include, e.g., a flow control valve, may be any suitable device capable of controlling and/or regulating the flow of a cryogen from cryogen source 102. Flow control device 106 may be manually-operated and/or remotely-operated by a process control system (not shown).

Cryogenic cleaning apparatus 100 may also include an auxiliary gas source 110 configured to deliver an auxiliary gas via a conduit 112, a flow control device 114, and conduits 116 and 118 (which are represented by arrows in FIG. 1 to illustrate direction of flow). Auxiliary gas source 110 may include, e.g., N₂, He, or Ar. In other embodiments, other suitable gases may be used. Conduits 112, 116, and 118 may be made of any material suitable for carrying an auxiliary gas. Flow control device 114, which may include, e.g., a flow control valve, may be any suitable device capable of controlling and/or regulating the flow of a gas from auxiliary gas source 110. Flow control device 114 may be manually-operated and/or remotely-operated by the process control system (not shown) that may also remotely-operate flow control device 106.

Cryogenic cleaning apparatus 100 may further include a nozzle 120. Nozzle 120 may include an inlet 122, a main passage 124, and an outlet 126. Inlet 122 may be coupled to conduit 108. Nozzle 120 may be configured to receive a cryogen from cryogen source 102 via conduit 104, flow control device 106, and conduit 104 through inlet 122 and into main passage 124. Nozzle 120 may also include one or more auxiliary gas inlets 128 and an equal number of auxiliary gas outlets 130. Nozzle 120 may have more or less than the two auxiliary gas inlets 128 and outlets 130 shown. Auxiliary gas inlets 128 may each be configured to receive an auxiliary gas from auxiliary gas source 110 via conduit 112, flow control device 114, and respective conduits 116 and 118. Auxiliary gas outlets 130 may be configured to completely or partially surround a nozzle exit 132 and to mix auxiliary gas received through respective auxiliary gas inlets 128 with a cryogen passing through outlet 126 at nozzle exit 132 to form a cryogen spray 134. Cryogen spray 134 may include cryogenic liquid droplets and/or cryogen ice having an average droplet size of between about 5 and 200 microns. In some embodiments, cryogen spray 134 may be formed without an auxiliary gas mixing with the cryogen passing through outlet 126.

Cryogenic cleaning apparatus 100 may further include a processing chamber 136 that may be configured to at least partially enclose a heated substrate holder 138 therein. Processing chamber 136 may be any structure suitable for cleaning substrates as described herein, and need not be a vacuum chamber. Heated substrate holder 138 may be configured to receive thereon a substrate 140 to be cleaned in processing chamber 136. Heated substrate holder 138 may be positioned such that substrate 140 is a distance D1 from nozzle exit 132. In some embodiments, distance D1 may be between about 1 and 20 cm.

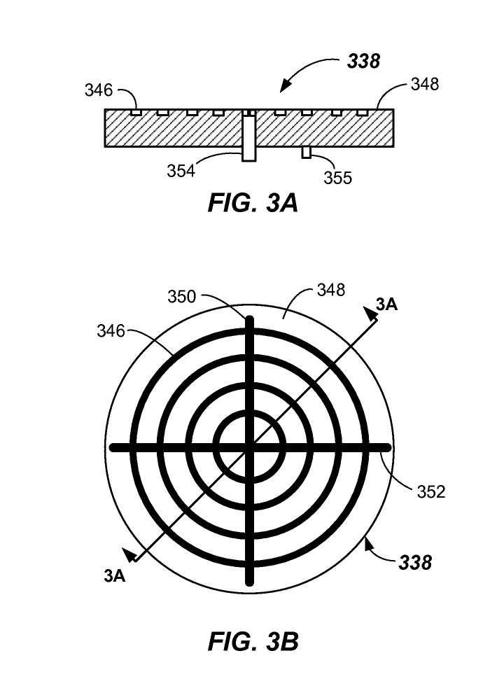

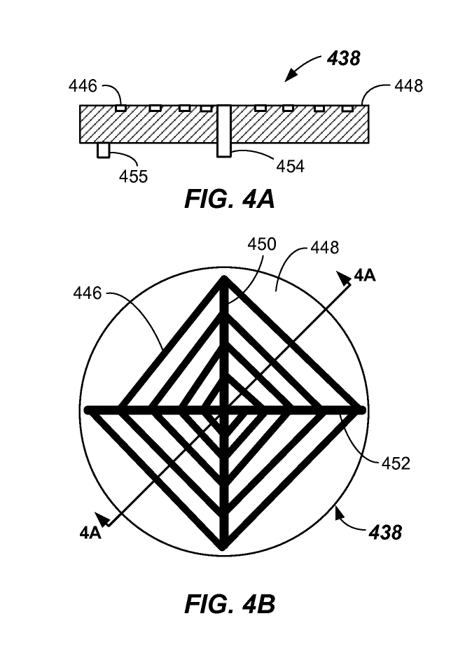

Heated substrate holder 138 may be coupled to a heat source 142, which may provide, e.g., a heated liquid or gas that circulates through the heated substrate holder 138 (as described in more detail below in connection with FIGS. 3A, 3B, 4A, and 4B). The heated liquid or gas may be between about 30° C. and about 90° C., for example. In other embodiments, the liquid and/or gas may be heated to other suitable temperatures. In some embodiments, the heated gas may be, e.g., N₂, and the heated liquid may be, e.g., water. In other embodiments, other suitable gases and/or liquids may be used. In some embodiments, heat source 142 may be controlled by a heating controller 144. Heating controller 144 may be coupled to a sensor 145 in thermal contact with the heated substrate holder 138 to monitor the temperature of the heated substrate holder 138 and, when necessary, adjust the heat output of heat source 142. Sensor 145 may be a thermocouple, thermopile, or other temperature sensing device. In some embodiments, the heat source 142 may be an electrical heating device, and heating controller 144 may include a thermostat or similar device and corresponding control circuits that may control the heat output of heat source 142. Heat source 142 may be any suitable device that sufficiently heats the heated substrate holder 138 and/or substrate 140 to a desired operating temperature or temperature range for cleaning. For example, in some embodiments, heat source 142 may be capable of heating the heated substrate holder 138 and/or a substrate 140 to a desired operating temperature range of between about 30° C. and about 90° C. In other embodiments, heat source 142 may heat the heated substrate holder 138 and/or substrate 140 to other suitable operating temperatures above room temperature.

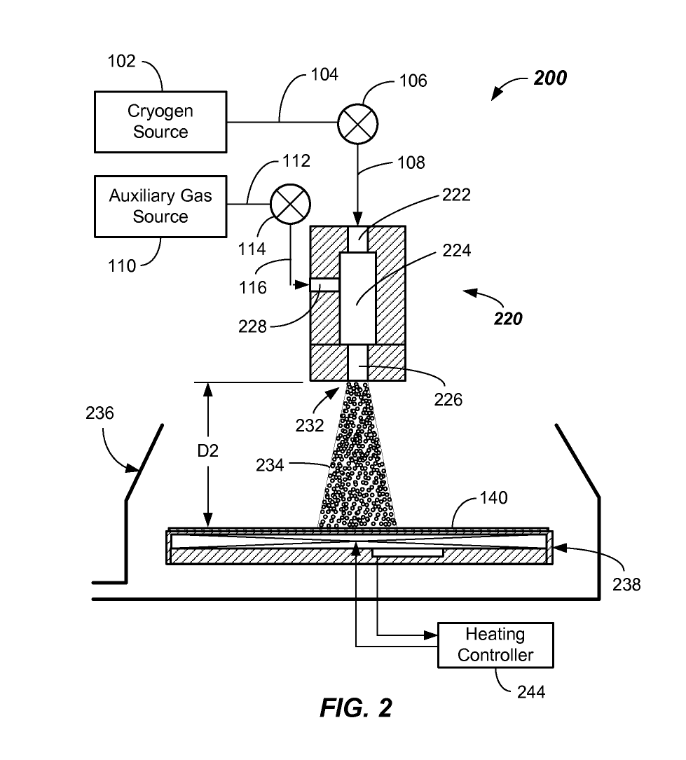

FIG. 2 illustrates a cross-sectioned side view of another embodiment of a cryogenic cleaning apparatus 200 and components thereof in accordance with one or more embodiments. Cryogenic cleaning apparatus 200 may include, as described above in connection with FIG. 1, cryogen source 102 configured to deliver a cryogen via conduit 104, flow control device 106, and conduit 108 (which is represented by an arrow in FIG. 2 to illustrate direction of flow). Cryogenic cleaning apparatus 200 may also include, as also described above in connection with FIG. 1, auxiliary gas source 110 configured to deliver an auxiliary gas via conduit 112, flow control device 114, and conduit 116 (which is represented by an arrow in FIG. 2 to illustrate direction of flow).

Cryogenic cleaning apparatus 200 may further include a nozzle 220. Nozzle 220 may include an inlet 222, a main passage 224, and an outlet 226. Inlet 222 may be coupled to conduit 108. Nozzle 220 may be configured to receive a cryogen from cryogen source 102 via conduit 104, flow control device 106, and conduit 108 through inlet 222 and into main passage 224. Nozzle 220 may also include an auxiliary gas inlet 228 coupled to main passage 224. In some embodiments, nozzle 220 may have more than one auxiliary gas inlet 228 coupled to the main passage 224. Auxiliary gas inlet 228 may be coupled to conduit 116 and configured to receive an auxiliary gas from auxiliary gas source 110 via conduit 112, flow control device 114, and conduit 116. Auxiliary gas received through auxiliary gas inlet 228 may flow into main passage 224 to mix with the cryogen received through inlet 222. Main passage 224 may be considered a mixing chamber. The cryogen/auxiliary gas mixture may pass through outlet 226 at nozzle exit 232 to form a cryogen spray 234. Cryogen spray 234 may be similar or identical to spray 134, as described above in connection with FIG. 1, and may include cryogenic liquid droplets and/or cryogen ice having an average droplet size of between about 5 microns and about 200 microns. In some embodiments, cryogen spray 234 may be formed without an auxiliary gas mixing with the cryogen in main passage 224.

Cryogenic cleaning apparatus 200 may further include processing chamber 236, which may be similar or identical to processing chamber 136 as described above in connection with FIG. 1. Processing chamber 236 may be configured to enclose a heated substrate holder 238, and may be any structure suitable for cleaning substrates as described herein. Processing chamber 236 need not be a vacuum chamber. Heated substrate holder 238 may be configured to receive thereon a substrate 140 to be cleaned in processing chamber 236. Heated substrate holder 238 may be positioned such that substrate 140 is a distance D2 from nozzle exit 132. In some embodiments, distance D2, which may be the same as distance D1 of FIG. 1, may be between about 1 cm and about 20 cm.

Heated substrate holder 238 may have a built-in heat source, which may be, e.g., an electrical heating device capable of heating the heated substrate holder 238 and/or a substrate 140 to a desired operating temperature or temperature range. In some embodiments, a desired temperature range may be between about 30° C. and about 90° C. In other embodiments, the heated substrate holder 238 and/or substrate 140 may be heated to other suitable temperatures above room temperature. A heating controller 244 may be coupled to heated substrate holder 238 to monitor a temperature of the heated substrate holder 238 and to accordingly adjust the heat output of the built-in heat source as necessary to maintain the desired operating temperature or temperature range. Heating controller 244 may be any suitable device capable of monitoring the temperature of the heated substrate holder 238 and of controlling the built-in heat source.

By optimizing the auxiliary gas flow rate, the substrate to nozzle distances D1 and D2, and the droplet size produced in cryogenic cleaning apparatus 100 and/or 200, the momentum of the spray 134, 234 may be controlled, and cleaning process speed can be controlled. By heating the substrate holder 338 and combining that with the momentum transfer of the cryogen spray, small particles, such as less than 40 nm in average particle size, may be more readily removed. Accordingly, cleaning efficiency may therefore be improved without damage to device structures that may have been previously fabricated on substrate 140.

FIGS. 3A and 3B illustrate a cross-sectioned side view and a top plan view, respectively, of a heated substrate holder 338 that may be used in cryogenic cleaning apparatus 100 and/or 200 in accordance with one or more embodiments. Heated substrate holder 338 may include a plurality of concentric circle channels 346 (only one of which is labeled in FIGS. 3A and 3B), which may extend inward (i.e., downward as shown in FIG. 3A) from a surface 348 of heated substrate holder 338. A substrate 140 (not shown in FIGS. 3A and 3B) may be received on top of surface 348. Heated substrate holder 338 may also include linear interconnecting channels 350 and 352 to couple the concentric circle channels 346 to each other to produce one or more flow paths. Channels 346, 350, and/or 352 may be coupled to a main delivery conduit 354, which may extend completely through the center of heated substrate holder 338 (alternatively, main delivery conduit 354 may extend through other suitable locations of heated substrate holder 338). Main delivery conduit 354 may be coupled to a heat source (not shown) that provides a heated liquid or gas to heated substrate holder 338. In some embodiments, the heated liquid may be, e.g., water, and the heated gas may be, e.g., N₂. In other embodiments, other suitable gases and/or liquids may be used. In some embodiments, the liquid or gas may be heated to between about 30° C. and about 90° C. In other embodiments, the liquid and/or gas may be heated to other suitable temperatures. The heated liquid or gas received through main delivery conduit 354 may flow through the linear connecting channels 350 and 352 and the concentric circle channels 346 to heat a substrate 140 positioned on surface 348 to a desired temperature or temperature range. Delivery channels 350, 352, and 346 may be configured to have one or more outlets 355 delivering the flow of the liquid and/or gas back to a heat source. Any suitable flow pattern may be provided. Delivery channels 350, 352, and 346 may be formed from suitable tubes or conduits.

FIGS. 4A and 4B illustrate a cross-sectioned side view and a top plan view, respectively, of another embodiment of a heated substrate holder 438 that may be used in cryogenic cleaning apparatus 100 and/or 200 in accordance with one or more embodiments. Instead of concentric circle channels as in heated substrate holder 338, heated substrate holder 438 may include a spiral channel 446, which may extend inward (i.e., downward as shown in FIG. 4A) from a surface 448 of heated substrate holder 438. A substrate 140 (not shown in FIGS. 4A and 4B) may be received on top of surface 448. Heated substrate holder 438 may also include linear interconnecting channels 450 and 452 to couple the spiral channel 446 at various points. Channels 446, 450, and/or 452 may be coupled to a main delivery conduit 454, which may extend completely through the center of heated substrate holder 438 (alternatively, main delivery conduit 454 may extend through other suitable locations of heated substrate holder 438). Main delivery conduit 454 may be coupled to a heat source (not shown) that provides a heated liquid or gas to heated substrate holder 438. In some embodiments, the heated liquid may be, e.g., water, and the heated gas may be, e.g., N₂. In other embodiments, other suitable gases and/or liquids may be used. In some embodiments, the liquid or gas may be heated to between about 30° C. and about 90° C. In other embodiments, the liquid and/or gas may be heated to other suitable temperatures. The heated liquid or gas received through main delivery conduit 454 may flow through the linear connecting channels 450 and 452 and the spiral channel 446 to heat a substrate 140 positioned on surface 448 to a desired temperature or temperature range. Delivery channels 450, 452, and 446 may be configured to have one or more outlets 455 delivering the flow of the liquid and/or gas back to a heat source. Any suitable flow pattern may be provided. Delivery channels 450, 452, and 446 may be formed from suitable tubes or conduits.

In alternative embodiments, channel configurations other than those shown for heated substrate holders 338 and/or 438 in FIGS. 3A, 3B, 4A, and 4B may be used. In other alternative embodiments, channels 346, 350, 352 and/or channels 446, 450, and 452 may be replaced with internal passages that extend just at and/or below respective surfaces 348 and 448.

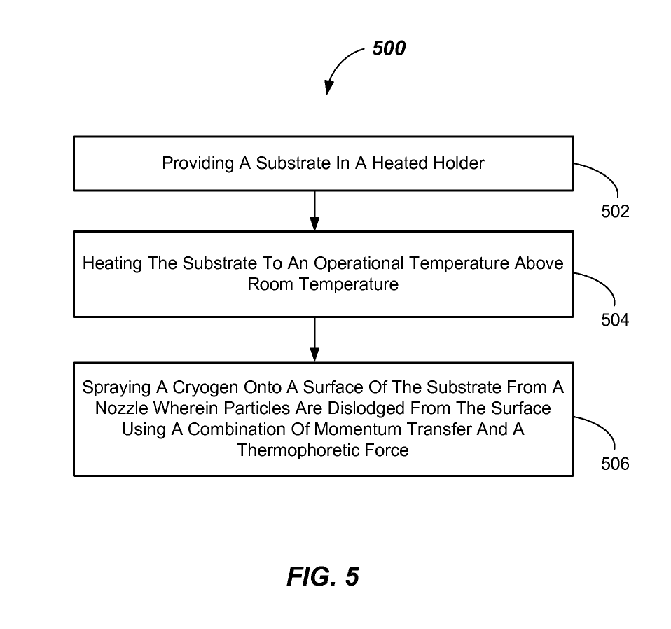

FIG. 5 illustrates a method 500 of cleaning a substrate (e.g., substrate 140), and in particular a method of cleaning a substrate after undergoing a planarization or other polishing process in accordance with one or more embodiments. Method 500 includes, at process block 502, providing a substrate (e.g., substrate 140) in a heated holder (e.g., heated substrate holder 138 and/or 238). The substrate may be, e.g., a semiconductor wafer. The heated holder may be coupled to a heat source which, in some embodiments, may heat the substrate via a heated liquid such as water or a heated gas such as N₂. In some embodiments, the liquid and/or gas may be heated to between about 30° C. and about 90° C. In other embodiments, the liquid and/or gas may be heated to any other suitable temperature above room temperature. In some embodiments, the heated holder may include a substrate chuck or platform that has, e.g., concentric circle or spiral channels, conduits or passages disposed throughout or near a top surface thereof to deliver the heat generated by the heat source to the substrate. In some embodiments, the heat source may be controllable. The heat source may heat the substrate in any suitable manner. In other embodiments, the heater may be an electrical resistance heater.

At process block 504, method 500 may include heating the substrate to a temperature above room temperature. In some embodiments, the substrate may be heated to between about 30° C. and about 90° C. In other embodiments, the substrate may be heated to any other suitable temperature.

Method 500 may include, at process block 506, spraying a cryogen onto a surface of the substrate from a nozzle. The nozzle may be, e.g., nozzle 120 or 220. The spraying may cause particles on the surface of the substrate to be dislodged from the surface of the substrate by momentum transfer, a thermophoretic force, and/or combinations of both. In some embodiments, the spraying of the cryogen may commence after the substrate has been in contact with the heated holder for about 5 seconds or until the substrate has reached an approximately steady state temperature. The cryogen may include, e.g., N₂, Ar, or CO₂. In some embodiments, method 500 may include assisting the spraying of the cryogen with an auxiliary gas, which may include, e.g., N₂, He, or Ar. The spraying may produce cryogenic liquid droplets and/or a cryogen ice, which may have an average droplet size of between about 5 microns and about 200 microns. In some embodiments, the spraying removes particles that may be about 40 nm or smaller from a substrate surface.

Note that in some embodiments method 500 does not utilize a vacuum chamber in which to be performed.

Accordingly, while the invention has been disclosed in connection with example embodiments thereof, it should be understood that other embodiments may fall within the scope of the invention, as defined by the following claims.

The invention claimed is:

1. A cryogenic cleaning apparatus, comprising:
a source of cryogen adapted to deliver a cryogen;
a nozzle coupled to the source of cryogen, the nozzle including a main passage adapted to receive the cryogen and one or more auxiliary gas inlets adapted to supply an auxiliary gas from an auxiliary gas source and to mix with the cryogen either within the nozzle or at a nozzle exit of the nozzle; and
a heated holder adapted to receive a substrate to be cleaned.

2. The cryogenic cleaning apparatus of claim 1, comprising an auxiliary gas inlet.

3. The cryogenic cleaning apparatus of claim 1, wherein the one or more auxiliary gas inlets are coupled to one or more auxiliary gas outlets that surround a nozzle exit.

4. The cryogenic cleaning apparatus of claim 1, wherein the one or more auxiliary gas inlets are coupled into the main passage.

5. The cryogenic cleaning apparatus of claim 1, wherein the heated holder is coupled to a heat source.

6. The cryogenic cleaning apparatus of claim 5, wherein the heat source is controllable.

7. The cryogenic cleaning apparatus of claim 1, wherein the cleaning apparatus is devoid of a vacuum chamber.

8. The cryogenic cleaning apparatus of claim 1, wherein the auxiliary gas comprises N₂, He, or Ar.

9. The cryogenic cleaning apparatus of claim 1, wherein the cryogen comprises N₂, Ar, or CO₂.

10. A method of cleaning a substrate, comprising:
providing a substrate in a heated holder;
heating the substrate to an operational temperature above room temperature; and
spraying a cryogen onto a surface of the substrate from a nozzle wherein particles are dislodged from the surface using a combination of momentum transfer and a thermophoretic force.

11. The method of claim 10, comprising assisting the spraying of the cryogen with an auxiliary gas.

12. The method of claim 10, comprising heating the substrate between about 30° C. and about 90° C.

13. The method of claim 10, wherein the spraying the cryogen commences after being in contact with the heated holder for about 5 seconds.

14. The method of claim 10, wherein the spraying produces a cryogen ice.

15. The method of claim 13, wherein the spraying produces a cryogen ice having an average droplet size of between about 5 microns and about 200 microns.

16. The method of claim 13, wherein the spraying removes particles that are 40 nm or smaller.
